(19) United States
(12) Patent Application Publication
(10) Pub. No.: US 2025/0089155 A1
(43) Pub. Date: Mar. 13, 2025

(54) TRANSMISSION MEDIA FOR DIGITAL SIGNALS AND ELECTRONIC DEVICE

(71) Applicant: AUTOX TECH PTE. LTD., SINGAPORE (SG)

(72) Inventors: Luoqi Tang, Shenzhen (CN); Xuhui Tao, Shenzhen (CN); Pingan Ding, Shenzhen (CN); Zhenan Guo, Shenzhen (CN)

(73) Assignee: AUTOX TECH PTE. LTD., SINGAPORE (SG)

(21) Appl. No.: 18/884,128

(22) Filed: Sep. 13, 2024

(30) Foreign Application Priority Data
Sep. 13, 2023 (CN) 2023111828715

(51) Int. Cl. H05K 1/02

(52) U.S. Cl. CPC H05K 1/0239; H05K 1/0242

(57) ABSTRACT

A digital signal transmission media includes a first signal transmission module and a second signal transmission module capable of relative motion with the first signal transmission module. The first signal transmission module includes a first circular conductor not fully closed. The second signal transmission module includes a second circular conductor not fully closed. The first circular conductor and the second circular conductor are arranged with a common center, and the first circular conductor and the second circular conductor rotating relative to each other. Signal coupling formed between the first circular conductor and the second circular conductor, enables one of the first signal transmission module and the second signal transmission module to transmit signals to the other.

This non-provisional patent application claims priority under 35 U.S.C. § 119 from Chinese Patent Application No. 202311182871.5 filed on Sep. 13, 2023, the entire content of which is incorporated herein by reference.

### TECHNICAL FIELD

The disclosure relates to communication technologies, particularly to a digital signal transmission media and electronic equipment.

### BACKGROUND

In the design of products such as robotic arms and LiDAR, there exist two distinct hardware structures featuring axial motion. To achieve high-speed digital communication between the two hardware circuits that move axially, existing solutions typically rely on wireless communication technology. This involves incorporating Analog-to-Digital Converter (ADC) and Digital-to-Analog Converter (DAC) circuits, as well as RF transceiver circuits, to facilitate high-speed digital communication between the two systems. However, these existing solutions not only complicate the hardware design but also significantly increase product costs due to the use of high-bandwidth ADC circuits.

### SUMMARY

This application provides a digital signal transmission media and electronic device with a simple structure and high reliability.

Firstly, there is a digital signal transmission media provided, The digital signal transmission media includes a first signal transmission module and a second signal transmission module capable of relative motion with the first signal transmission module. The first signal transmission module includes a first circular conductor not fully closed. The second signal transmission module includes a second circular conductor not fully closed. The first circular conductor and the second circular conductor are arranged with a common center, and the first circular conductor and the second circular conductor rotating relative to each other. Signal coupling formed between the first circular conductor and the second circular conductor, enables one of the first signal transmission module and the second signal transmission module to transmit signals to the other.

In the second aspect, an electronic device that applies a digital signal transmission media is also provided. The electronic device includes a relatively rotating first and second component, as well as the digital signal transmission media mentioned above. The first and second signal transmission modules in the digital signal transmission media are respectively set on the first and second components.

The above digital signal transmission media and electronic devices form signal coupling between two rotating circular conductors, achieving close range coupling communication. Due to the fact that this application achieves communication through signal coupling between circular conductors, there is no need for modulation processing or modulation and demodulation circuits, which reduces costs. At the same time, there is no need for mutations in inductive or capacitive components such as LC, resulting in better reliability.

### BRIEF DESCRIPTION OF THE DRAWINGS

In order to provide a clearer explanation of the embodiments or technical solutions in the present application or prior art, a brief introduction will be given below to the accompanying drawings required in the embodiments or prior art description. It is evident that the accompanying drawings in the following description are only some embodiments of the present application. For those skilled in the art, other accompanying drawings can be obtained based on the structures shown in these drawings without creative labor.

FIG. 1 is a schematic diagram of a digital signal transmission media provided in accordance with a first embodiment.

FIG. 2 is a schematic diagram of the first circular conductor and the second circular conductor provided in accordance with a first embodiment.

FIG. 3 is a schematic diagram of the first circular conductor and the second circular conductor provided in accordance with a second embodiment.

FIG. 4 is a schematic diagram of a structure of the digital signal transmission media.

FIG. 5 is a schematic diagram of the digital signal transmission media provided in accordance with the second embodiment.

FIG. 6 is a schematic diagram of the digital signal transmission media provided in accordance with a third embodiment.

FIG. 7 is a schematic diagram of the digital signal transmission media provided in accordance with a fourth embodiment.

FIG. 8 is a schematic diagram of the digital signal transmission media provided in accordance with a fifth embodiment.

FIG. 9 is a schematic diagram of the digital signal transmission media provided in accordance with a sixth embodiment.

FIG. 10 is a schematic diagram of an electronic device using the digital signal transmission media provided in accordance with a first embodiment.

The implementation, functional characteristics, and advantages of the purpose of this application will be further explained in conjunction with the embodiments, with reference to the accompanying drawings.

### DETAILED DESCRIPTION OF THE EMBODIMENTS

In order to make the purpose, technical solution, and advantages of this application clearer and clearer, the following will provide further detailed explanations of this application in conjunction with the accompanying drawings and embodiments. It should be understood that the specific embodiments described here are only intended to explain the present application and are not intended to limit the present application. Based on the embodiments in this application, all other embodiments obtained by ordinary technical personnel in this field without creative labor fall within the scope of protection of this application.

The terms “first”, “second”, “third”, “fourth”, etc. (if any) in the specification and claims of this application, as well as the accompanying drawings, are used to distinguish similar planning objects and do not need to be used to describe specific order or sequence. It should be understood that the data used in this way can be interchanged in appropriate cases, in other words, the described embodiments are implemented in order other than those illustrated or described here. In addition, the terms “including” and “having”, as well as any variations thereof, may also include other content, such as processes, methods, systems, products, or equipment that include a series of steps or units, not necessarily limited to those clearly listed, but may include other steps or units that are not clearly listed or inherent to these processes, methods, products, or equipment.

It should be noted that the descriptions related to “first”, “second”, etc. in this application are only for descriptive purposes and cannot be understood as indicating or implying their relative importance or implying the quantity of technical features indicated. Therefore, the features limited to “first” and “second” can explicitly or implicitly include one or more of these features. In addition, the technical solutions between various embodiments can be combined with each other, but must be based on what ordinary technical personnel in the art can achieve. When the combination of technical solutions conflicts or cannot be achieved, it should be considered that the combination of such technical solutions does not exist and is not within the scope of protection required by this application. Since this disclosure achieves communication via signal coupling between circular conductors, modulation processing and modulation/demodulation circuits are unnecessary, thereby reducing costs. Furthermore, there is no requirement for alterations to inductive or capacitive components like LC, contributing to enhanced reliability.

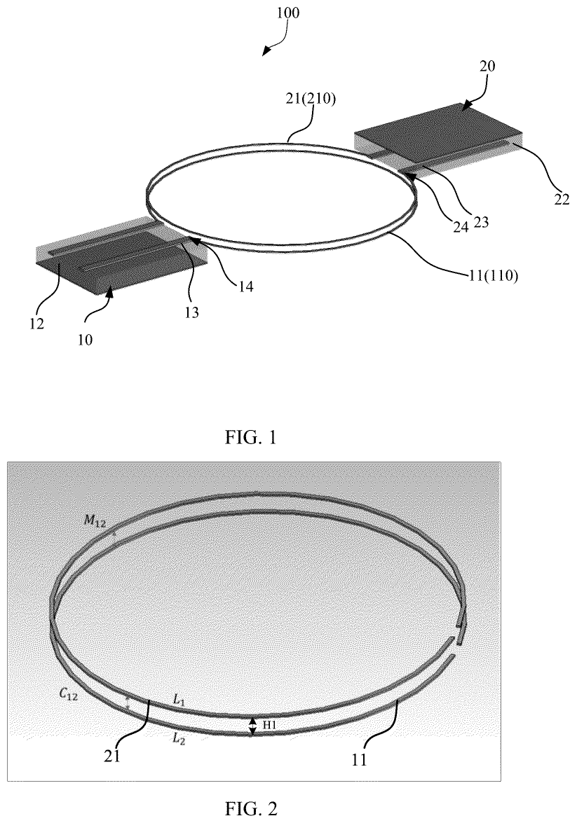

Referring to FIG. 1, a structural diagram of a digital signal transmission media 100 provided in accordance with a first embodiment. The digital signal transmission media 100 includes a first signal transmission module 10, and a second signal transmission module 20 that rotate with each other. Signal transmission is performed between the first signal transmission module 10 and the second signal transmission module 20. The digital signal transmission media 100 is utilized in electronic devices such as LiDAR and robotic arms which feature two separate hardware structures for the axial motion. It is understood that the first signal transmission module 10 and the second signal transmission module 20 are positioned between two separate components involved the axial motion, meaning that the two components rotate relative to each other, and the signal transmission is required between the two separate components. Taking radar as an example, one of the two different separate can be a component having an optical transceiver that performing photoelectric signal conversion; the other component can be a system processor that analyzes and calculates electrical signals. The first signal transmission module 10 is equipped with a first circular conductor 11, and the second signal transmission module 20 is equipped with a second circular conductor 21. The first circular conductor 11 and the second circular conductor 21 are positioned at the same center and interval, enabling signal coupling between the first circular conductor 21 and the second circular conductor 22, thereby facilitating communication between the first signal transmission module 10 and the second signal transmission module 20.

It is understood that one of the first circular conductor 11 and the second circular conductor 21 carries a changing signal, and when the first circular conductor 11 and the second circular conductor 21 rotate relative to each other, the other generates an induced electromotive force due to electromagnetic induction, which in turn gives rise to an induced current.

Furthermore, the rotation method between the first circular conductor 11 and the second circular conductor 21 is to keep one end of the first circular conductor 11 and the second circular conductor 21 stationary and the other end rotating; or, both ends of the first circular conductor 11 and the second circular conductor 21 can rotate in the same direction simultaneously; or, the first circular conductor 11 and the second circular conductor 21 can rotate in opposite directions, but both ends of the first circular conductor 11 and the second circular conductor 21 rotate simultaneously. That is to say, as long as there is relative rotation between the first circular conductor 11 and the second circular conductor 21. More specifically, the first signal transmission module 10 and the second signal transmission module 20 are respectively mounted on the rotating mechanism, which drives the the first signal transmission module 10 and the second signal transmission module 20 into relative rotation. For example, the rotating mechanism maintains one of the first signal transmission module 10 and the second signal transmission module 20 in motion while the other is stationary or both may rotate at different speeds or directions, thereby causing the first signal transmission module 10 and the second signal transmission module 20 to move relative to each other.

In this embodiment, the communication between the first circular conductor 11 and the second circular conductor 21 is achieved by themselves, without need for modulation processing or the addition of modulation and demodulation circuits, thereby reducing cost. At the same time, there is no requirement for adjustments or changes in inductive or capacitive components, such as LC, resulting in better reliability.

Projections of the areas enclosed by the first circular conductor 11 and the second circular conductor 21 respectively onto a plane parallel to planes in which the first circular conductor 11 and the second circular conductor 21 lie, partially or completely overlap. The first circular conductor 11 and the second circular conductor 21 are respectively rings not fully closed. That is to say, the first circular conductor 11 and the second circular conductor 21 are respectively circular conductors with openings. The first circular conductor 11 and the second circular conductor 21 can be made of copper material. The first circular conductor 11 includes at least one first sub circular conductor 110. The second circular conductor 21 includes at least one second sub circular conductor 210.

Referring to FIG. 1 again, in this embodiment, the diameter of the first circular conductor 11 and the diameter of the second circular conductor 21 are identical, and the first circular conductor 11 and the second circular conductor 21 are spaced in the axial direction. An interval H1 exists in the axial direction between the first circular conductor 11 and the second circular conductor 21 In other words, when projected onto that is parallel to the planes in which the first circular conductor 11 and the second circular conductor 21 lie, the projections of the areas enclosed by each conductor overlaps completely.

In some embodiments, the diameter of the first circular conductor 11 and the diameter of the second circular conductor 21 are different. The first circular conductor 11 and the second circular conductor 21 are arranged in a mutually nested configuration, such that there is a gap between the first circular conductor 11 and the second circular conductor 21 along the radial direction That is to say, the projected onto a plane parallel to the plane in which the first circular conductor 11 and the second circular conductor 21 lie, the projections of the areas enclosed by each of the first circular conductor 11 and the second circular conductor 21, but the projections of the gaps between them do not overlap.

Furthermore, the first circular conductor 11 includes a first sub circular conductor 110. The second circular conductor 21 includes a second sub circular conductor 210.

Furthermore, the first signal transmission module 10 further includes a circuit board 12, and two first terminals 13 positioned on the first circuit board 12. The second signal transmission module 20 also includes a second circuit board 22 and two second terminals 23 positioned on the second circuit board 22. Two first terminals 13 are configured to electrically connect the two ends of the first circular conductor 11 to form a first circuit 14. Two second terminals 23 are configured to electrically connect two ends of the second circular conductor 21 to form a second circuit 24. The two first terminals 13 can be wires soldered onto the circuit board 12 or terminals attached to the circuit board 12. The two second terminals 23 are respectively terminals or wires positioned on the second circuit board 22. In this embodiment, both the two first terminals 13 and the two second terminals 23 are wires. That is to say, the wiring configurations of the first circuit board 12 and the second circuit board 22, corresponding to the first circular conductor 11 and the second circular conductor 21, are identical. The digital signal transmission media 100 employs differential signal wiring, enabling differential signal transmission.

Referring to FIG. 2, a schematic diagram of the spacing between the first circular conductor 11 and the second circular conductor 21 in the axial direction is illustrated.

The first circular conductor 11 and the second circular conductor 21 possess self inductance, while mutual inductance and mutual capacitance exist between the first circular conductor 11 and the second circular conductor 21. Appropriate self inductance can ensure that the high-speed signal waveform does not experience distortions such as collapse and oscillation. High mutual inductance, on other hand, is the crucial for ensuring effective signal coupling from one of the first circular conductor 11 and the second circular conductor 21 to the other. However, due to LC resonance, mutual capacitance can limit the available communication bandwidth. A calculation formula for resonant frequency is as follows:

$$f = \frac{1}{2 π \sqrt{L C}}$$

Where f indicates the frequency; L indicates the inductance; C indicates mutual tolerance. Among them, the larger the range of variation in frequency f of the signal, the wider the bandwidth of the signal.

Referring to FIG. 3, it illustrates that the diameter of the first circular conductor 11 differs from the diameter of the second circular conductor 21. The first circular conductor 11 and the second circular conductor 21 are arranged in a mutually nested configuration. Similarly, each of the first circular conductor 11 and the second circular conductor 21 possesses its own self-inductance, and there exists mutual inductance and mutual capacitance between the first circular conductor 11 and the second circular conductor 21.

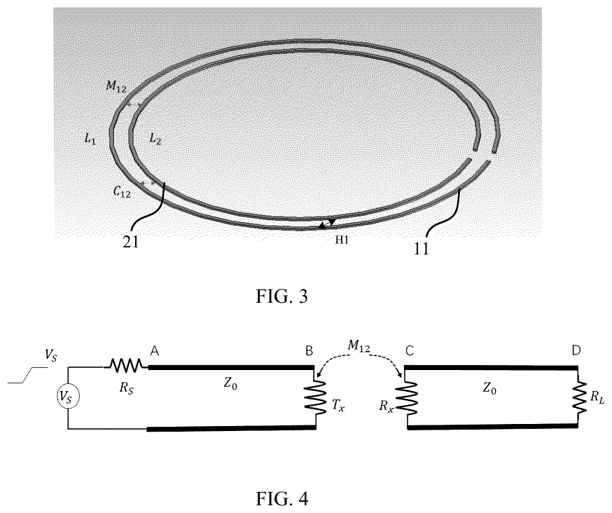

Referring to FIG. 4, it shows a topology diagram of the signal transmission principle for the digital signal transmission media 100. The first signal transmission module 10 and the second signal transmission module 20 rotate to transmit the signals. One of the first circular conductor 11 and the second circular conductor 21 functions as the transmitting end TX, while the other serves as the receiving end RX. There exits a characteristic impedance associated with the mutual inductance transmission line between the transmitting end TX and the receiving end RX. The first circuit 14 is formed at the sending end TX, while the second circuit 24 is formed at the receiving end RX. The first circuit 14 includes source impedance and transmitter impedance. The second circuit 24 includes load impedance and receiver impedance. A calculation formula for transmitting signals is as follows:

$${V}_{A} = {V}_{S} \frac{{Z}_{0}}{{Z}_{0} + {R}_{S}} \qquad ( 1 )$$

$${V}_{B} = ( 1 + {Γ}_{B} ) {V}_{A} \qquad ( 2 )$$

$${Γ}_{B} = \frac{{z}_{{effT}_{x}} - {Z}_{0}}{{Z}_{{effT}_{x}} + {Z}_{0}} \qquad ( 3 )$$

$${z}_{{effT}_{x}} = \frac{{Z}_{{T}_{x}} * {Z}_{{M}_{12}}}{{Z}_{{T}_{x}} + {Z}_{{M}_{12}}} \qquad ( 4 )$$

$${z}_{{effR}_{x}} = \frac{{Z}_{{R}_{x}} * {Z}_{{M}_{12}}}{{Z}_{{R}_{x}} + {Z}_{{M}_{12}}} \qquad ( 5 )$$

$${V}_{{M}_{12}} = ( 1 + {Γ}_{M} ) * {V}_{B} \qquad ( 6 )$$

$${Γ}_{M} = \frac{{Z}_{{T}_{x}} - {Z}_{{M}_{12}}}{{Z}_{{T}_{x}} + {Z}_{{M}_{12}}} \qquad ( 7 )$$

$${V}_{{R}_{x}} = ( 1 + {Γ}_{c} ) * {V}_{{M}_{12}} \qquad ( 8 )$$

$${Γ}_{C} = {V}_{{R}_{x}} \frac{{Z}_{0}}{{Z}_{0} + {Z}_{{effR}_{x}}} \qquad ( 9 )$$

$${V}_{C} = {V}_{{R}_{x}} \frac{{Z}_{0}}{{Z}_{0} + {z}_{e f f {R}_{x}}} \qquad ( 10 )$$

$${V}_{D} = ( 1 + {Γ}_{D} ) {V}_{C} \qquad ( 11 )$$

$${Γ}_{D} = \frac{{R}_{L} - {Z}_{0}}{{R}_{L} + {Z}_{0}} \qquad ( 12 )$$

Wherein, V_{S} indicates the initial level of the signal; V_{D} indicates the level at point D, which is the input level of the load; V_{A} indicates the level of point A; V_{B} indicates the level of point B; V_{C} indicates the level at point C; V_{M}_{₁₂} indicates the level of mutual inductance; V_{R}_{ₓ} presents the level at the receiving end RX, Z_{effT}_{ₓ} indicates the impedance of the transmitting end TX; Z_{effR}_{ₓ} indicates the impedance of the receiving end; Γ_{B} indicates the reflection coefficient between the impedance of the first circular conductor 11 and the impedance of the PCB transmission line; Γ_{M} indicates the reflection coefficient between the impedance of the first circular conductor 11 and the impedance of the second circular conductor 21; Γ_{C} indicates the reflection coefficient between the impedance of the second circular conductor 21 and the impedance of the PCB transmission line; Γ_{D} indicates the reflection coefficient between the load impedance of the receiving end and the impedance of the PCB transmission line; Z_{M}_{₁₂} indicates the mutual inductance impedance.

Due to the wideband characteristics of digital signals, transmission necessitates meeting requirements across a wide frequency range. This embodiment leverages the inherent inductance and mutual inductance characteristics of both the receiving end RX and the transmitting end TX, while taking into account the coupling mutual capacitance between the them, and the limitations on communication bandwidth, to achieve close-range coupling communication. To maintain a high voltage level, the impedance of both the transmitting end and the receiving end are set to a relatively high values, necessitating a higher mutual inductance value and a larger coupling area.

Furthermore, according to a mutual capacitance calculation formula, it is as follows:

$${C}_{12} = \frac{ε S}{D} \qquad ( 13 )$$

Wherein, C₁₂ indicates mutual tolerance; ε indicates the area of the electrode plate; S indicates the distance between the plates.

There is mutual capacitance coupling between the transmitting end TX and the receiving end RX of the signal, forming a parallel relationship with each other. The mutual capacitance impedance is:

$${Z}_{{C}_{12}} = \frac{1}{2 π {fC}_{12}} \qquad ( 14 )$$

The impedance after parallel connection is:

$${Z}_{e f f} = \frac{{Z}_{{C}_{12}} * {Z}_{{M}_{12}}}{{Z}_{{C}_{12}} + {Z}_{{M}_{12}}} \qquad ( 15 )$$

Wherein, the impedance Z_{T}_{ₓ} of the transmitting end, the impedance Z_{R}_{ₓ} of the receiving end, the mutual inductance M₁₂, and the mutual capacitance impedance Z_{C}_{₁₂} can be optimized by adjusting the diameter and position relationship of the first circular conductor 11 and the second circular conductor 21, as well as the quantity of sub circular conductors contained in each, so as to achieve the effect of direct transmission of digital signals. More specifically, the larger the diameter of the first circular conductor 11 and the second circular conductor 21, the greater self inductance for each. Assuming the relative positions of the first circular conductor 11 and the second circular conductor 21 remain constant, a larger diameter also enhances mutual inductance, mutual capacitance, resonant frequency, and low-frequency coupling effect, alibeit ate the cost of reducing the available communication bandwidth.

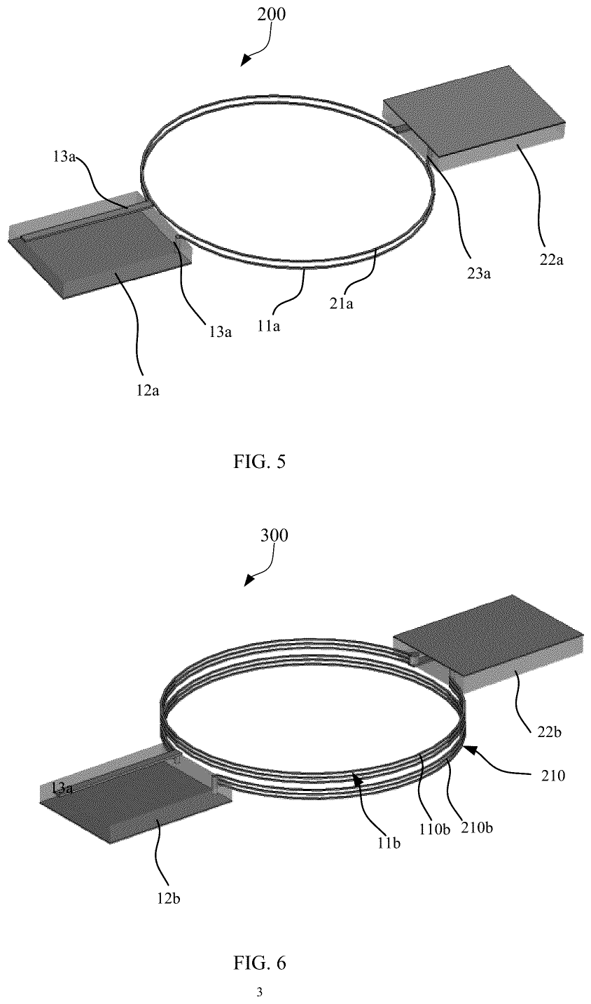

Referring to FIG. 5, it illustrates a structural diagram of the digital signal transmission media 200 in accordance with a second embodiment. The difference between the digital signal transmission media 200 in the second embodiment and the digital signal transmission media 100 in the first embodiment is that: there are two first terminals 13a, one of which is a wire soldered onto the circuit board 12a, and the other is a terminal soldered onto the circuit board 12a. The two second terminals 23 are respectively terminals soldered onto the second circuit board 22a, and the interval H2 between the first circular conductor 11a and the second circular conductor 21a is less than the interval H1. The changes in the first terminal 13a and the second terminal 23a, respectively, signify a modification in the wiring method of the digital signal transmission media 200. As a result, a single ended wiring signal wiring signal transmission method has been employed, enabling single ended signal transmission. This capability provides versatility for different application environments and capability with various chips.

Referring to FIG. 6, it illustrates the structural diagram of the digital signal transmission media 300 provided in the third embodiment of this application. The difference between the digital signal transmission media 300 provided in the third embodiment and the digital signal transmission media 200 provided in the second embodiment is that the first circular conductor 11b includes multiple first sub circular conductors 110b, and the second circular conductor 21b includes multiple second sub circular conductors 210b. The diameter of the first circular conductor 11d is larger than that of the second circular conductor 21d, which includes multiple sub circular conductors. Due to multiple sub circular conductors, the digital signal transmission media 100 has the following three characteristics. 1. Under specific structural and processing requirements, it can meet the requirements of the sender's self sensing Ltx. 2. Multiple rings can increase mutual inductance M12. 3. The change in mutual capacitance C12 is relatively small. Due to the above three characteristics, it is possible to meet the communication bandwidth and cost requirements of the design to the greatest extent possible based on the actual product shape structure and processing technology requirements.

Referring to FIG. 7, it illustrates a structural diagram of the digital signal transmission media 400 in accordance with a fourth embodiment. The difference between the digital signal transmission media 400 of the fourth embodiment and the digital signal transmission media 300 of the third embodiment lies in the configuration of the terminals. Specifically, the two first terminals 13c and the two second terminals 23c are terminals are situated directly on the first circuit board 12c and the second circuit board 22c, respectively. Furthermore, the changes in configurations of the first terminal 13a and the second terminal 23a necessitate a modification in, the wiring method of the circuit board. Consequently, the digital signal transmission media 400 of the fourth embodiment employs a differential signal wiring method, enabling differential signal transmission. This adaptation enhances the versatility of the media, allowing it to be compatible with various application environments and suited for different chips compared to the digital signal transmission media 300.

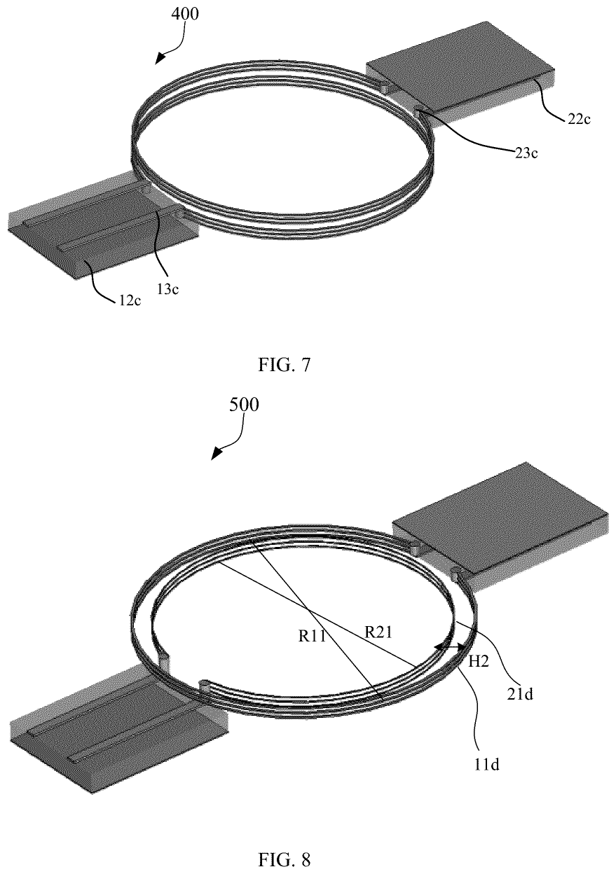

Referring to FIG. 8, it illustrates the structural diagram of the digital signal transmission media 500 in accordance with a fifth embodiment. The difference between the digital signal transmission media 500 of the fifth embodiment and the digital signal transmission media 400 of the fourth embodiment lies in the fact that the diameter R11 of the first circular conductor 11d is greater than the diameter R21 of the second circular conductor 21d, and furthermore, the first circular conductor 11d is arranged to surround and sheath the second circular conductor 21d externally. The nesting configuration, combined with the larger diameter of the first circular conductor 11d compared to the second circular conductor 21d, which may consist of multiple sub circular conductors, mutual inductance M12, thereby enhancing the coupling effect. Meanwhile, the passive increase in mutual capacitance C12 is relatively minimal due to the inherently small thickness of individual circular conductors 1.

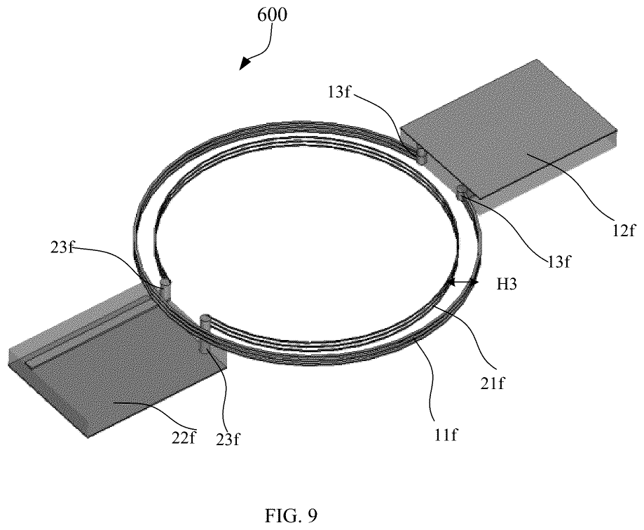

Referring to FIG. 9, it illustrates a structural diagram of the digital signal transmission media 600 in accordance with a sixth embodiment. The difference between the digital signal transmission media 600 of the sixth embodiment and the digital signal transmission media 500 of the fifth embodiment is that the two first terminals 13f are positioned on the first circuit board 12f, whereas the two second terminals 23f are mounted on the second circuit board 22f, respectively. In other words, the digital signal transmission media 600 of the sixth embodiment employs a single end signal wiring method to achieve single end signal transmission, which enhances compatibility with application environment suitable for various chips, similar to the digital signal media 300. Additionally, the distance H3 along the diameter direction between the first circular conductor 11f and the second circular conductor 21f is greater than the corresponding distance H2 between the first circular conductor 11d and the second circular conductor 21d.

It can be understood that the desired transmission performance of the digital signal transmission media can be achieved by adjusting the diameter, position relationship, and quantity of sub circular conductors of the first and second circular conductors. For instance, by optimizing the performance parameters such as the transmitting impedance, receiving impedance, mutual inductance, and mutual capacitance impedance.

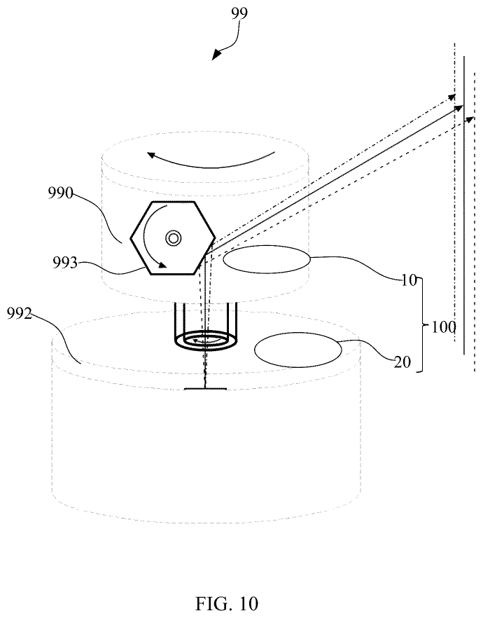

Referring to FIG. 10, it illustrates a schematic diagram of electronic device 99 using the digital signal transmission media provided in the above embodiment.

The electronic device 99 includes a first component 990, a second component 992, a rotating mechanism 993 that rotates both the first component 990 and the second component 992, and any digital signal transmission media provided by any embodiment. In this embodiment, the digital signal transmission media 100 is used as an illustrative example. Specifically, the first circular conductor 10 and the second circular conductor 20 of the digital transmission media 100 are respectively mounted on the first component 990 and the second component 992.

Obviously, technical personnel in this field can make various modifications and variations to the present application without departing from the spirit and scope of the present application. In this way, if these modifications and variations of the present application fall within the scope of the claims and their equivalent technologies, the present application also intends to include these modifications and variations.

The above listed examples are only the preferred embodiments of this application, and of course, they cannot be used to limit the scope of the rights of this application. Therefore, the equivalent changes made according to the claims of this application still fall within the scope of this application.

1. A digital signal transmission media, the digital signal transmission media comprising:
a first signal transmission module, comprising: a first circular conductor not fully closed; and
a second signal transmission module capable of relative motion with the first signal transmission module, the second signal transmission module comprising a second circular conductor not fully closed, the first circular conductor and the second circular conductor arranged with a common center, and the first circular conductor and the second circular conductor rotating relative to each other, signal coupling formed between the first circular conductor and the second circular conductor, enabling one of the first signal transmission module and the second signal transmission module to transmit signals to the other.

2. The digital signal transmission media of claim 1, wherein the first circular conductor and the second circular conductor have the same diameter and are spaced in an axial direction.

3. The digital signal transmission media of claim 2, wherein a diameter of the first circular conductor is larger than that of the second circular conductor, and the first circular conductor surrounds the second circular conductor.

4. The digital signal transmission media of claim 3, wherein the first circular conductor comprises at least one first sub circular conductor; the second circular conductor comprises at least one second sub circular conductor.

5. The display adaptation method of claim 4, wherein the first circular conductor comprises a plurality of parallel identical first sub circular conductors, and each first sub circular conductor is arranged at a common center; the second circular conductor comprises a plurality of parallel identical second sub circular conductors arranged at a common center.

6. The digital signal transmission media of claim 4, wherein each of the first sub circular conductors and each of the second sub circular conductors are non closed circular rings.

7. The digital signal transmission media of claim 6, wherein the first signal transmission module further comprises two first terminals, and the second signal transmission module further comprises two second terminals, two ends of the first circular conductor are electrically connected to the two first terminals, forming a first circuit; two ends of the second circular conductor are electrically connected to the second terminals, forming a second circuit.

8. The digital signal transmission media of claim 7, wherein the first signal transmission module further comprises a first circuit board, and the second signal transmission module further comprises a second circuit board, the first sub circular conductor and the second sub circular conductor are respectively positioned on the first circuit board and the second circuit board.

9. The digital signal transmission media of claim 8, wherein the two first terminals are respectively terminals or wires mounted to the first circuit board; the two second terminals are respectively terminals or wires mounted to on the second circuit board.

10. An electronic device, comprising
a first component;
a second component; and
a digital signal transmission media, comprising:
a first signal transmission module mounted to the first component, comprising:
a first circular conductor not fully closed; and
a second signal transmission module, mounted to the second component, and comprising a second circular conductor not fully closed, the first circular conductor and the second circular conductor arranged with a common center, and the first circular conductor and the second circular conductor rotating relative to each other, signal coupling formed between the first circular conductor and the second circular conductor, enabling one of the first signal transmission module and the second signal transmission module to transmit signals to the other.

11. The electronic device of claim 10, wherein the first circular conductor and the second circular conductor have the same diameter and are spaced in an axial direction.

12. The electronic device of claim 11, wherein a diameter of the first circular conductor is larger than that of the second circular conductor, and the first circular conductor surrounds the second circular conductor.

13. The electronic device of claim 12, wherein the first circular conductor comprises at least one first sub circular conductor; the second circular conductor comprises at least one second sub circular conductor.

14. The electronic device of claim 13, wherein the first circular conductor comprises a plurality of parallel identical first sub circular conductors, and each first sub circular conductor is arranged at a common center; the second circular conductor comprises a plurality of parallel identical second sub circular conductors arranged at a common center.

15. The electronic device of claim 14, wherein each of the first sub circular conductors and each of the second sub circular conductors are non closed circular rings.

16. The electronic device of claim 15, wherein the first signal transmission module further comprises two first terminals, and the second signal transmission module further comprises two second terminals, two ends of the first circular conductor are electrically connected to the two first terminals, forming a first circuit; two ends of the second circular conductor are electrically connected to the second terminals, forming a second circuit.

17. The electronic device of claim 16, wherein the first signal transmission module further comprises a first circuit board, and the second signal transmission module further comprises a second circuit board, the first sub circular conductor and the second sub circular conductor are respectively positioned on the first circuit board and the second circuit board.

18. The electronic device of claim 17, wherein the two first terminals are respectively terminals or wires mounted to the first circuit board; the two second terminals are respectively terminals or wires mounted to on the second circuit board.
